(19) United States
(12) Patent Application Publication
(10) Pub. No.: US 2014/0042110 A1
(43) Pub. Date: Feb. 13, 2014

(54) POLE ASSEMBLY

(71) Applicant: JUN CUI, Shenzhen City (CN)

(72) Inventor: JUN CUI, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/593,484

(22) Filed: Aug. 23, 2012

(30) Foreign Application Priority Data
Aug. 9, 2012 (CN) 2012102819390

(51) Int. Cl. H01L 23/32

(52) U.S. Cl. 211/41.1

(57) ABSTRACT

A pole assembly includes a supporting pole, a connecting pole, and a reinforcing pole. A first end of the reinforcing pole is pivotably connected to a first end of the supporting pole. A first end of the connecting pole is pivotably connected to a second end of the supporting pole. The connecting pole and the supporting pole each have a U-shaped cross-section. A locking slot is defined in a second end of the reinforcing pole. A locking portion is formed from a middle portion of the connecting pole. When to use the pole assembly, the locking portion extends through the locking slot and is bent to contact with reinforcing pole, to connect the second end of the reinforcing pole to the middle portion of the connecting pole.

### BACKGROUND

1. Technical Field

The present disclosure relates to poles, and particularly, to a pole assembly for supporting photovoltaic modules.

2. Description of Related Art

A pole assembly for photovoltaic modules may be made by welding a plurality of metal poles together with a non-flexible structure, which results in inconvenience in transportation of the pole assembly.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an exploded, isometric view of an embodiment of a pole assembly.

FIG. 2 is an enlarged view of a circled portion II of FIG. 1.

FIG. 3 is an assembled, isometric view of the pole assembly of FIG. 1.

FIG. 4 is an enlarged view of a circled portion IV of FIG. 3.

FIG. 5 is a cross-sectional view taken along the line of V-V of FIG. 3.

FIG. 6 is an enlarged view of a circled portion VI of FIG. 5.

### DETAILED DESCRIPTION

The disclosure, including the accompanying drawings in which like references indicate similar elements, is illustrated by way of examples and not by way of limitation. It should be noted that references to “an” or “one” embodiment in this disclosure are not necessarily to the same embodiment, and such references mean “at least one.”

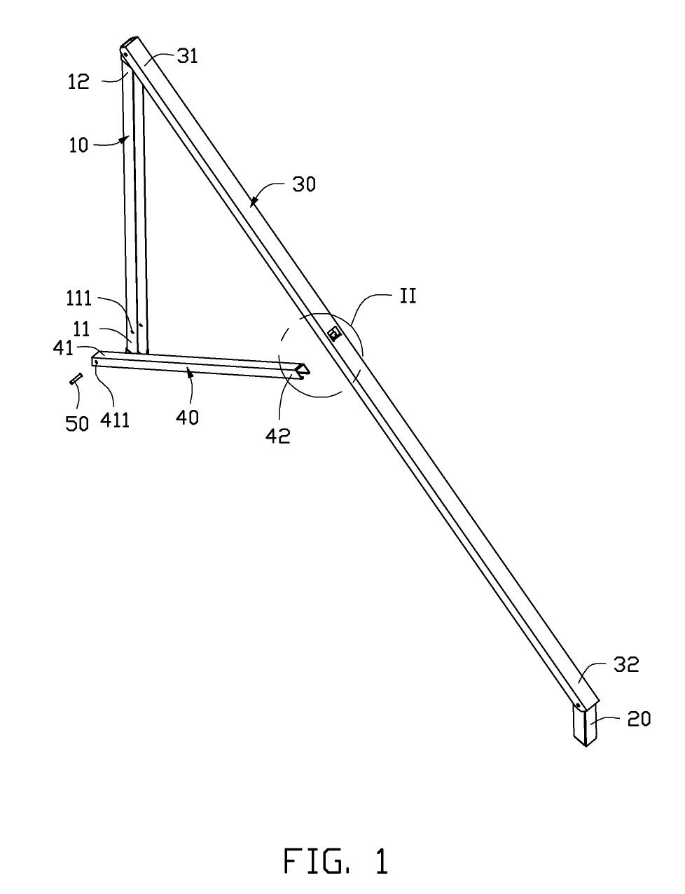

Referring to FIG. 1, an embodiment of a pole assembly includes a supporting pole 10, a fixing pole 20, a connecting pole 30, a reinforcing pole 40, and a pivoting shaft 50. The supporting pole 10 and the connecting pole 30 each have a substantially U-shaped cross-section.

The supporting pole 10 includes a first end 11 and a second end 12. The supporting pole 10 defines a pivot hole 111 adjacent to the first end 11. The connecting pole 30 includes a first end 31 and a second end 32. The first end 31 is pivotably connected to the second end 12. The second end 32 is pivotably connected to a first end of the fixing pole 20.

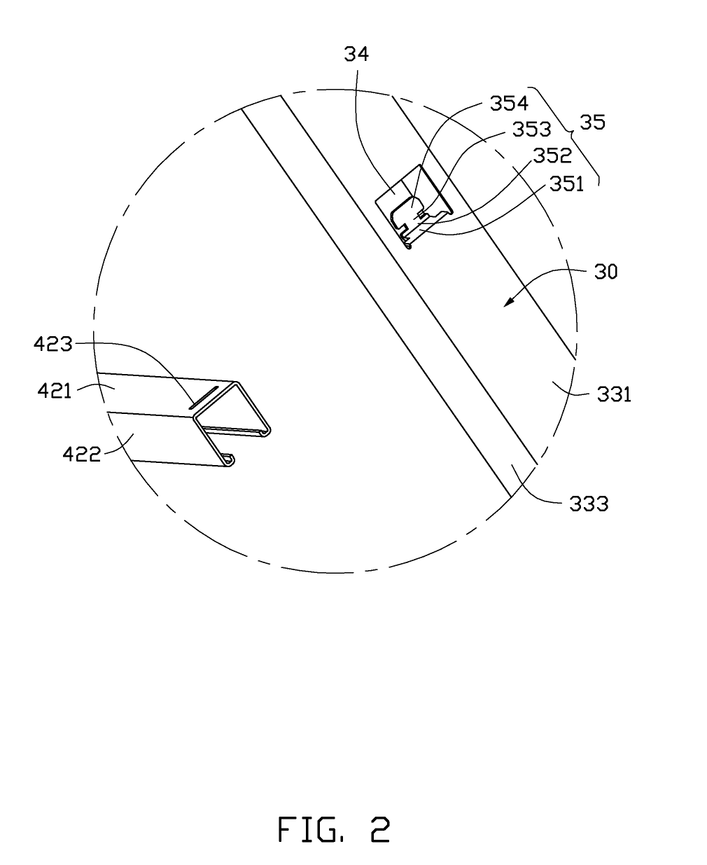

Referring to FIG. 2, the connecting pole 30 includes a middle plate 331 and two side plates 333 extending from opposite sides of the middle plate 331. A through hole 34 is defined in a middle portion of the middle plate 331. A locking portion 35 extends into the through hole 34 from a sidewall bounding the through hole 34 and adjacent to the second end 32. The locking portion 35 includes a jointing plate 351 extending perpendicularly from the middle plate 331, a blocking plate 352 perpendicularly extending from the jointing plate 351 toward an opposite sidewall bounding the through hole 34, a connecting plate 353 extending from the blocking plate 352, and a locking plate 354 extending from the connecting plate 353. The width of the connecting plate 353 is less than the widths of the blocking plate 352 and the locking plates 354. The blocking plate 352, the connecting plate 353, and the locking plate 354 are coplanar and together form an H shape.

The reinforcing pole 40 includes a first end 41 and a second end 42. The reinforcing pole 40 defines a through hole 411 near the first end 41. The reinforcing pole 40 includes a middle wall 421 and two sidewalls 422 extending from opposite sides of the middle wall 421. The middle wall 421 defines a locking slot 423 adjacent to the second end 42.

In assembly, the first end 41 is pivotably connected to the first end 11 through the pivoting shaft 50 pivotably extending through the through hole 411 and the pivot hole 111.

When need to transport or store the pole assembly, the reinforcing pole 40 is rotated to be received in the supporting pole 10. The supporting pole 10 together with the reinforcing pole 40 is then rotated to be received in the connecting pole 30. The fixing pole 20 is rotated to be received in the connecting pole 30. Therefore, the supporting pole 10, the fixing pole 20, and the reinforcing pole 40 are all received in the connecting pole 30, so the pole assembly can be conveniently transferred.

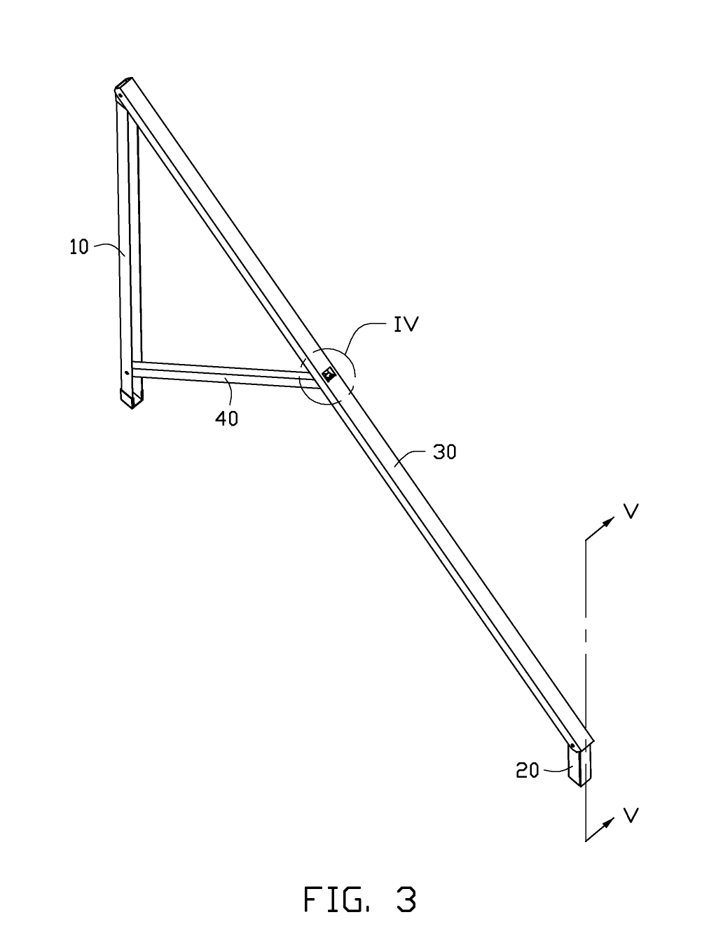

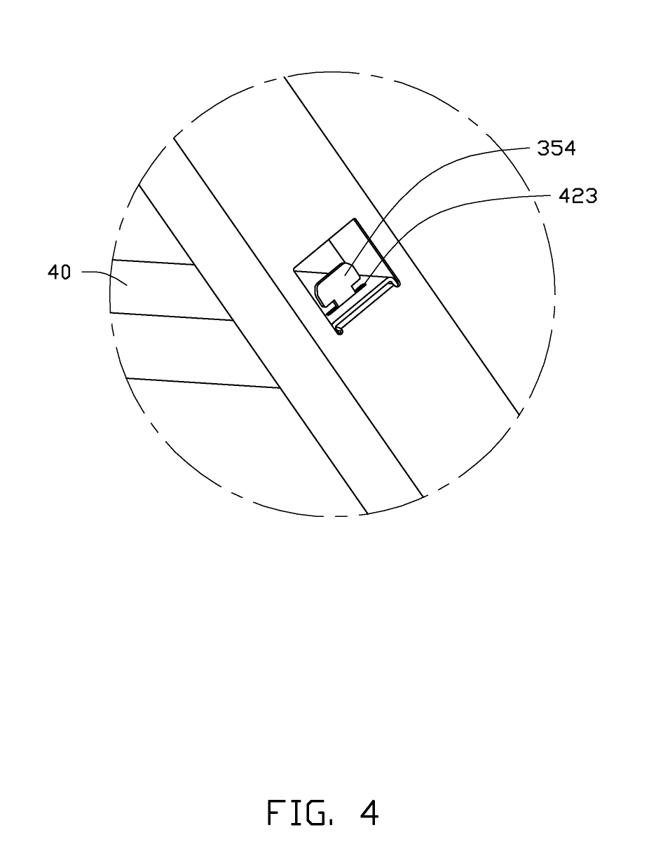

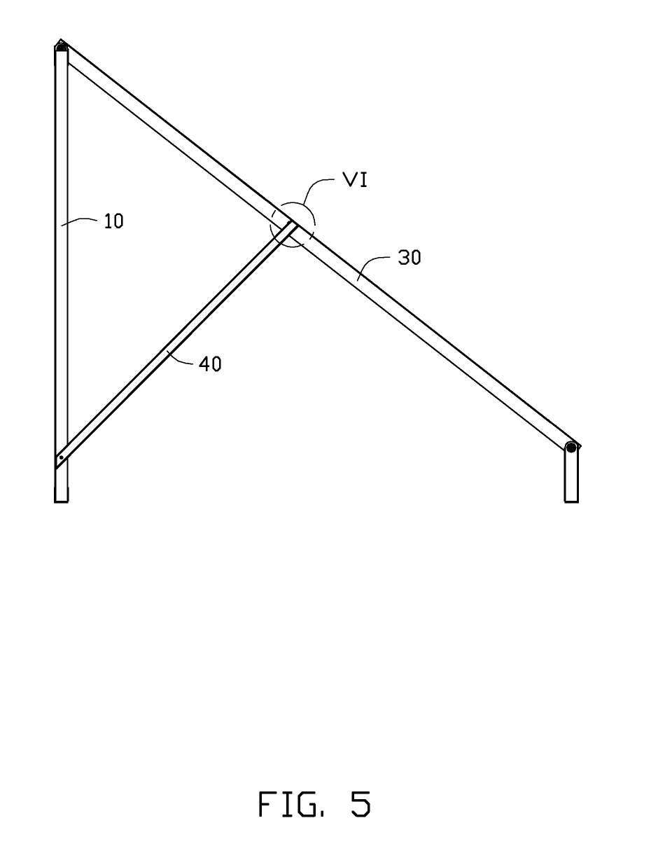

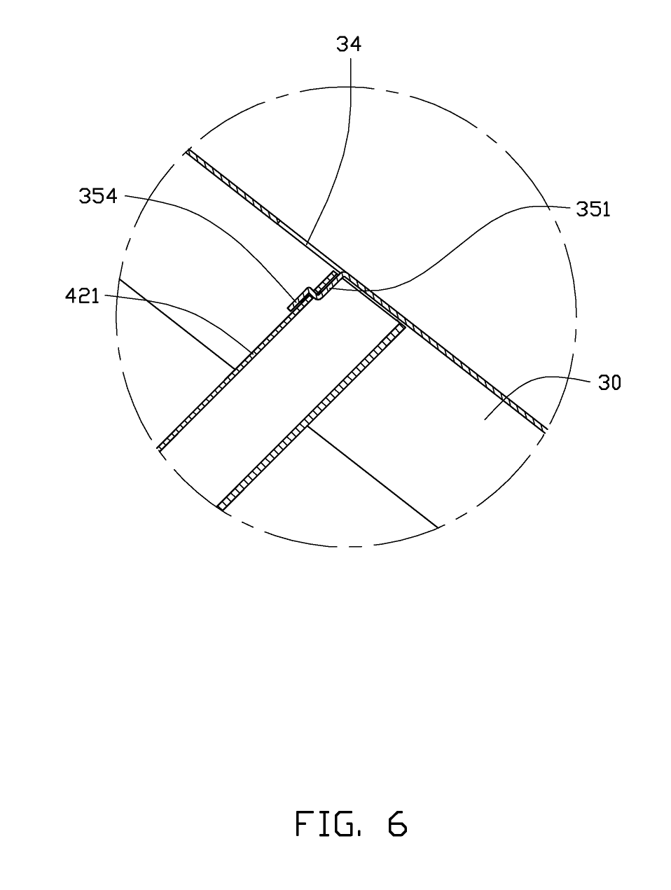

Referring to FIG. 3 and FIG. 4, when need to use the pole assembly to support photovoltaic modules, the locking portion 354 extends through the locking slot 423, the second end 42 is supported on the jointing plate 351. The blocking plate 352 engages in the locking slot 423. The locking plate 354 is then bent to contact with the middle wall 421, to fix the second end 42 to the middle portion of the connecting pole 30 as shown in FIG. 5 and FIG. 6. The first end 11 and a second end of the fixing pole 20 are fixed to a supporting flat, such as ground. Therefore, the connecting pole 30 can be used to support the photovoltaic modules. The connecting plate 353 is narrow relative to the blocking plate 352 and the locking plate 354, which is easy to bend the locking plate 354.

In the embodiment, the pole assembly can be folded to save space, which is convenient for transportation. To use, the locking portion 35 locks to the locking slot 423 to fix the second end 42 to the middle portion of the connecting pole 30, thus the pole assembly can be conveniently assembled.

It is to be understood, however, that even though numerous characteristics and advantages of the embodiments have been set forth in the foregoing description, together with details of the structure and function of the embodiments, the disclosure is illustrative only, and changes may be made in detail, especially in the matters of shape, size, and arrangement of parts within the principles of the disclosure to the full extent indicated by the broad general meaning of the terms in which the appended claims are expressed.

1. A pole assembly, comprising:
a supporting pole;
a connecting pole; and
a reinforcing pole;
wherein the supporting pole and the connecting pole each having a substantially U-shaped cross section;
wherein a first end of the reinforcing pole is pivotably connected to a first end of the supporting pole, a first end of the connecting pole is pivotably connected to a second end of the supporting pole;
wherein a second end of the reinforcing pole defines a locking slot, a locking portion is formed from a middle portion of the connecting pole, and the locking portion comprises a locking plate;
wherein, in response to the second end of the reinforcing pole not being locked by the locking portion, the reinforcing pole is operable to be rotated around the first end of the supporting pole to be received in the supporting pole, the supporting pole together with the reinforcing pole is then rotated around the second end of the supporting pole to be received in the connecting pole; and
wherein, in response to a need to put pole assembly in use, the locking portion is inserted into the locking slot, the locking plate is then bent towards the reinforcing pole, to fix the second end of the reinforcing pole to the middle portion of the connecting pole.

2. The pole assembly of claim 1, wherein the connecting pole comprises a middle plate and two side plates extending from opposite sides of the middle plate, a through hole is defined in a middle portion of the middle plate, the locking portion extends into the through hole from a sidewall bounding the through hole.

3. The pole assembly of claim 2, wherein the locking portion further comprises a jointing plate extending perpendicularly from the middle plate, a blocking plate extending from the jointing plate, and a connecting plate extending from the blocking plate, the locking plate extends from the connecting plate.

4. The pole assembly of claim 3, wherein the locking portion extends through the locking slot, the second end of the reinforcing pole is supported on the jointing plate, the blocking plate engages in the locking slot, the locking plate is operable to be bent to contact with the middle wall, to fix the second end of the reinforcing pole to the middle portion of the connecting pole.

5. The pole assembly of claim 3, wherein a width of the connecting plate is less than a width of the blocking plate.

6. The pole assembly of claim 1, wherein a fixing pole is pivotably connected to a second end of the connecting pole.

7. The pole assembly of claim 6, wherein the fixing pole is rotatable around the second end of the connecting pole to be received in the connecting pole.
